(19) United States
(12) Patent Application Publication
(10) Pub. No.: US 2013/0200437 A1
(43) Pub. Date: Aug. 8, 2013

(54) METHOD OF FORMING NANOGAP PATTERN, BIOSENSOR HAVING THE NANOGAP PATTERN, AND METHOD OF MANUFACTURING THE BIOSENSOR

(71) Applicant: Kwan Goo Rha, Seongnam-si (KR)

(72) Inventor: Kwan Goo Rha, Seongnam-si (KR)

(73) Assignee: MICOBIOMED CO., LTD., Daejeon (KR)

(21) Appl. No.: 13/824,367

(22) PCT Filed: Oct. 18, 2011
(86) PCT No.: PCT/KR2011/007746

§ 371 Date: Mar. 17, 2013

(30) Foreign Application Priority Data
Oct. 21, 2010 (KR) 10-2010-0102738

(51) Int. Cl. H01L 21/306; H01L 29/66; G01N 27/414

(52) U.S. Cl. CPC H01L 21/30604; G01N 27/4146; H01L 29/66409
USPC 257/253; 438/703; 438/49

(57) ABSTRACT

Provided is a method of forming a nanogap pattern of a biosensor. First, an oxide layer is formed on a substrate and a first nitride layer is formed on the oxide layer. The first nitride layer is partially etched to form a first nitride layer pattern having a first gap that gradually narrows from a top portion to a bottom portion thereof and exposes the oxide layer. A second nitride layer is formed along the first nitride layer and along sidewalls and a bottom surface of the first gap. The second nitride layer is etched to form a second nitride layer pattern having a second gap narrower than the first gap on the sidewalls of the first gap. The oxide layer is etched by using the second nitride layer pattern as an etching mask to form an oxide layer pattern having a third gap, and thus, the nanogap pattern is completed.

### TECHNICAL FIELD

The present invention disclosed herein relates to a method of forming a nanogap pattern, a biosensor having the nanogap pattern, and a method of manufacturing the biosensor, and more particularly, to a method of forming a nanogap pattern that may form a nanogap pattern suitable for a biosensor, a biosensor having the nanogap pattern, and a method of manufacturing the biosensor.

### BACKGROUND ART

Biosensors are detectors that detect specific materials existing in living organisms, such as enzyme, antibody, and nucleic acid. The biosensors use electrical, chemical, and optical methods of detecting such materials. Among these biosensors, since a biosensor using the electrical detection method may rapidly detect a small amount of a material and a sensing circuit and a detection circuit may be simultaneously formed in a single chip, a small portable biosensor may be manufactured.

In order to manufacture such biosensor, a nanogap having a size of a material to be detected, i.e., a nanometer size, must be formed on an electrical circuit substrate, and since sensitivity of the biosensor increases as the size of the formed nanogap decreases, effective detection may be possible.

However, since forming a gap with a size of nanometer or less by using a typical lithography process may not only be complicated but may also have technical limitations and reproducibility may decrease as the size of the gap decreases, a nanometer-sized gap required for a high-performance biosensor may be difficult to be formed. Also, according to the related art, a silicon on insulator (SOI) substrate may be used as a substrate for forming the foregoing biosensor. However, since a manufacturing process of the SOI substrate is complicated, the price thereof is more expensive than that of a typical silicon wafer.

### DISCLOSURE OF THE INVENTION

### Technical Problem

The present invention provides a method of forming a nanogap pattern that may reproducibly form a nanogap having a desired size on a substrate.

The present invention also provides a biosensor including the nanogap pattern.

The present invention also provides a method of manufacturing a biosensor including the method of forming a nanogap pattern.

### Technical Solution

In accordance with an embodiment of the present invention, a method of forming a nanogap pattern may include forming an oxide layer on a substrate; forming a first nitride layer on the oxide layer; partially etching the first nitride layer to form a first nitride layer pattern having a first gap that exposes the oxide layer and gradually narrows from a top portion to a bottom portion thereof; forming a second nitride layer along the first nitride layer and along sidewalls and a bottom surface of the first gap; and etching the second nitride layer to form a second nitride layer pattern having a second gap narrower than the first gap on the sidewalls of the first gap.

The method of manufacturing a nanogap pattern may further include etching the oxide layer by using the second nitride layer pattern as an etching mask to form an oxide layer pattern having a third gap.

The first gap may have a micron size, and the second gap and the third gap may each have a nano size.

An inclination angle of the first gap may be in a range of 15 degrees to 75 degrees.

In accordance with another embodiment of the present invention, a biosensor may include a substrate; a nanogap pattern including an oxide layer pattern disposed on the substrate and having a third gap, a first nitride layer pattern disposed on the oxide layer pattern and having a first gap that partially exposes the oxide layer pattern around the third gap and gradually narrows from a top portion to a bottom portion thereof, and a second nitride layer pattern disposed on sidewalls of the first gap and the oxide layer pattern exposed by the first gap and having a second gap narrower than the first gap; and a gate electrode disposed on the nanogap pattern and including a gate conductive layer pattern.

The first gap may have a micron size, and the second gap and the third gap may each have a nano size.

An inclination angle of the first gap may be in a range of 15 degrees to 75 degrees.

In accordance with another embodiment of the present invention, a method of manufacturing a biosensor may include forming a nanogap pattern having a nanogap on a substrate; and forming a gate electrode including a gate conductive layer pattern on the nanogap pattern. The forming of the nanogap pattern having the nanogap may include: forming an oxide layer on the substrate; forming a first nitride layer on the oxide layer; partially etching the first nitride layer to form a first nitride layer pattern having a first gap that exposes the oxide layer and gradually narrows from a top portion to a bottom portion thereof; forming a second nitride layer along the first nitride layer and along sidewalls and a bottom surface of the first gap; etching the second nitride layer to form a second nitride layer pattern having a second gap narrower than the first gap on the sidewalls of the first gap; and etching the oxide layer by using the second nitride layer pattern as an etching mask to form an oxide layer pattern having a third gap.

The first gap may have a micron size, and the second gap and the third gap may each have a nano size.

An inclination angle of the first gap may be in a range of 15 degrees to 75 degrees.

### Advantageous Effects

According to the present invention, a second nitride layer formed along a first nitride layer pattern with a micro-sized first gap is dry etched to form a second nitride layer pattern with a nano-sized second gap smaller than the micro-sized first gap on sidewalls of the first gap. An oxide layer is etched by using the second nitride layer pattern as a mask to form an oxide layer pattern with a third gap having the same size as that of the second gap, and thus, a nanogap pattern may be formed. Also, the second gap having a desired size may be reproducibly formed by controlling a size of the first gap, a thickness of the second nitride layer, and time of the dry etching process.

A biosensor able to effectively detect a biomaterial may be manufactured by forming a gate electrode exposing the nano-sized gap on the nanogap pattern.

### BRIEF DESCRIPTION OF THE DRAWINGS

FIG. 1 is a flowchart illustrating a method of forming a pattern having a nanogap according to an embodiment of the present invention;

FIGS. 2 through 9 are cross-sectional views illustrating the method of forming a pattern having a nanogap illustrated in FIG. 1;

FIG. 10 is a cross-sectional view illustrating a biosensor according to an embodiment of the present invention;

FIG. 11 is a flowchart illustrating a method of manufacturing a biosensor according to an embodiment of the present invention; and

FIGS. 12 and 13 are cross-sectional views illustrating the method of manufacturing a biosensor illustrated in FIG. 11.

### MODE FOR CARRYING OUT THE INVENTION

Hereinafter, the present invention will be described below in more detail with reference to the accompanying drawings illustrating embodiments of the present invention. The present invention may, however, be embodied in different forms and should not be constructed as limited to the embodiments set forth herein. Rather, these embodiments are provided so that this disclosure will be thorough and complete, and will fully convey the scope of the present invention to those skilled in the art.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. It will be understood that, although the terms first, second, third etc. may be used herein to describe various elements, components, regions, layers and/or sections, these elements, components, regions, layers and/or sections should not be limited by these terms.

The terminology used herein is for the purpose of describing particular example embodiments only and is not intended to be limiting of the present inventive concept. Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The embodiment in the detailed description will be described with sectional views as ideal exemplary views of the present invention. Accordingly, shapes of the exemplary views may be modified according to manufacturing techniques and/or allowable errors. Therefore, the embodiments of the present invention are not limited to the specific shape illustrated in the exemplary views, but may include other shapes that may be created according to manufacturing processes. Areas exemplified in the drawings have general properties, and are used to illustrate a specific shape of a semiconductor package region. Thus, this should not be construed as limited to the scope of the present invention.

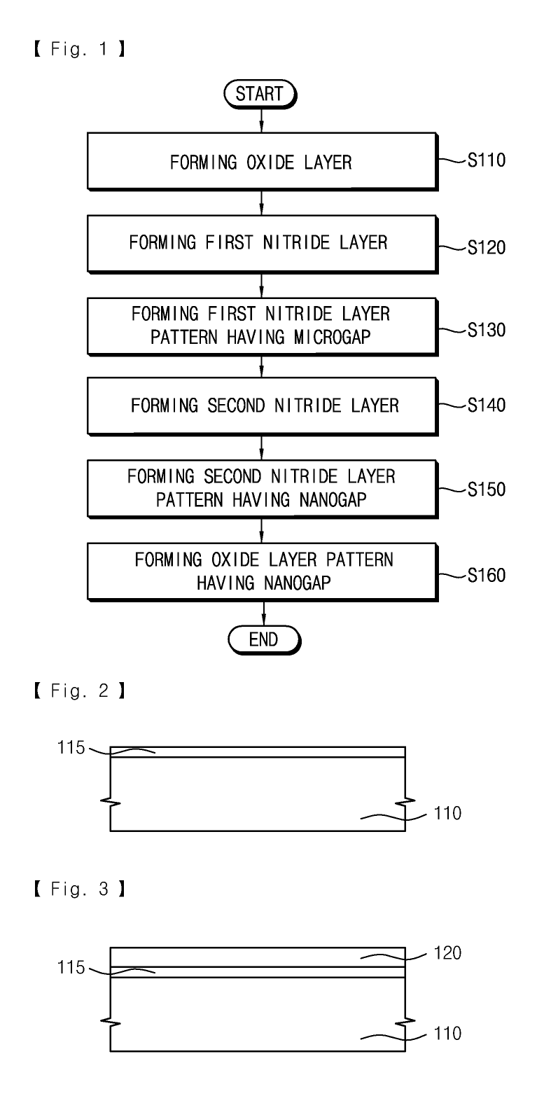

FIG. 1 is a flowchart illustrating a method of forming a pattern having a nanogap according to an embodiment of the present invention, and FIGS. 2 through 9 are cross-sectional views illustrating the method of forming a pattern having a nanogap illustrated in FIG. 1.

Referring to FIGS. 1 and 2, an oxide layer 115 is formed on a substrate 110 (S110). Herein, the substrate 110 may be a single crystal silicon substrate. Since a low cost single crystal substrate may be used as the substrate 110 instead of using a relatively expensive silicon on insulator (SOI) substrate, costs required during formation of a pattern having the nanogap may be reduced. For example, the oxide layer 115 may be formed by a thermal oxidation process. As another example, the oxide layer 115 may be formed by a chemical vapor deposition process. The oxide layer 115 may be a silicon oxide layer.

Referring to FIGS. 1 and 3, a first nitride layer 120 is formed on the oxide layer 115 (S120). The first nitride layer 120 may be formed by a chemical vapor deposition process. The first nitride layer 120 may be a silicon nitride layer.

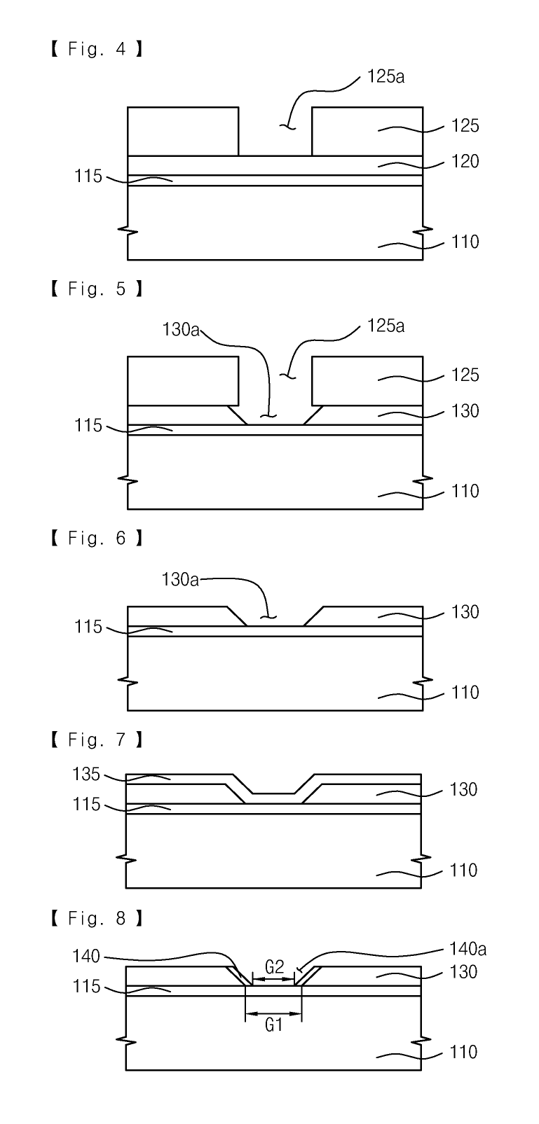

Referring to FIGS. 1 and 4, a pattern layer 125 having an opening 125a selectively exposing the first nitride layer 120 is formed on the first nitride layer 120. According to an embodiment of the present invention, a photoresist layer is formed on the first nitride layer 120 by coating a photoresist composition or attaching a photoresist film, and the pattern layer 125 may be formed on the first nitride layer 120 by selectively exposing and developing the photoresist layer.

A width of the opening 125a may have a micron size. For example, the width of the opening 125a may be in a range of about 1 μm to about 2 μm. Since the size of the opening 125a is relatively large, the pattern layer 125 may be easily formed and costs required for forming the pattern layer 125 may be reduced.

Referring to FIGS. 1 and 5, the first nitride layer 120 is etched by using the pattern layer 125 as an etching mask to form a first nitride layer pattern 130 having a first gap 130a exposing the oxide layer 115 (S130).

The etching process may be performed by alternatingly using an isotropic etching process and an anisotropic etching process. For example, the first nitride layer 120 is isotropically etched and the first nitride layer pattern 130 may then be formed by anisotropic etching. As another example, the first nitride layer 120 is anistropically etched and the first nitride layer pattern 130 may then be formed by isotropic etching.

It is described in the etching process that both the isotropic etching process and the anisotropic process are performed once. However, in some cases, the isotropic etching process and the anisotropic process may be performed many times.

Also, any one of the isotropic etching process and the anisotropic process may only be used in the etching process.

The isotropic etching may be performed through a wet etching process using an etchant. An example of the etchant may be a phosphoric acid (H₃PO₄) solution able to etch nitrides. The anisotropic etching may be performed through a dry etching process using an etching gas. Examples of the dry etching process may be plasma etching, ion beam milling, reactive ion etching (RIE), magnetically enhanced RIE (MERIE), inductively coupled plasma (ICP), transfer coupled plasma (TCP), and electron cyclotron resonance (ECR). The etching gas may include HBr gas, Cl₂ gas, and HeO₂ gas, or may include HBr gas and HeO₂ gas, or may include HBr gas and O₂ gas.

According to an embodiment of the present invention, the first gap 130a may be formed to have an inclined sidewall profile. Specifically, the first gap 130a has a shape that gradually narrows from a top portion to a bottom portion thereof. A size of the top portion of the first gap 130a is greater than that of the opening 125a and a size of the bottom portion of the first gap 130a is smaller than that of the opening 125a. Since the size of the opening 125a has a micron size, the first gap 130a also has a micron size.

Meanwhile, an inclination angle of sidewalls of the first gap 130a may be in a range of about 15 degrees to about 75 degrees. For example, the inclination angle of the sidewalls of the first gap 130a may be in a range of about 30 degrees to about 60 degrees.

In the case that the sidewalls of the first gap 130a has an inclination angle of less than about 15 degrees, inclination of the sidewalls of the first gap 130a is relatively low, and thus, it may be difficult to subsequently form a nanogap by using the first gap 130a.

In the case that the inclination angle of the sidewalls of the first gap 130a is greater than about 75 degrees, a second nitride layer pattern to be described later may be formed on the sidewalls of the first gap 130a. However, a gate electrode composed of a gate dielectric layer pattern and a gate conductive layer pattern may be difficult to be formed on the second nitride layer pattern.

Referring to FIGS. 1 and 6, the pattern layer 125 is removed. The pattern layer 125 may be removed by ashing and/or stripping process.

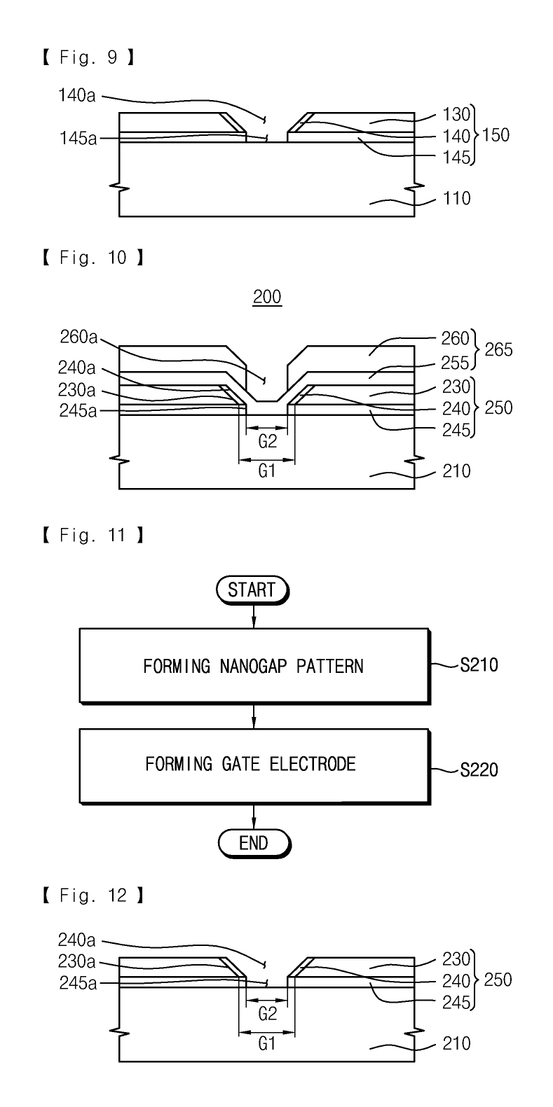

Referring to FIGS. 1 and 7, a second nitride layer 135 is formed along a top surface of the first nitride layer pattern 130 and along the sidewalls and a bottom surface of the first gap 130a (S140). The second nitride layer 135 may be formed by a chemical vapor deposition process and an atomic layer deposition process. The second nitride layer 135 may be the same material as the first nitride layer 120. For example, the second nitride layer 135 may be a silicon nitride layer.

At this time, the second nitride layer 135 may be formed to allow a thickness of the second nitride layer 135 formed on the sidewalls of the first gap 130a to be thicker than a thickness of the second layer 135 formed on the top surface of the first nitride layer pattern 130 and the bottom surface of the first gap 130a.

Referring to FIGS. 1 and 8, the second nitride layer 135 is anisotropically etched to form a second nitride layer pattern 140 having a second gap 140a on the side walls of the first gap 130a (S150). Specifically, since the second nitride layer 135 is etched to have a predetermined thickness by the anisotropic etching, the second nitride layer 135 formed on the top surface of the first nitride layer pattern 130 and the bottom surface of the first gap 130a is removed and the second nitride layer 135 formed on the sidewalls of the first gap 130a remains. Therefore, the second nitride layer 135 remaining on the sidewalls of the first gap 130a forms the second nitride layer pattern 140.

The anisotropic etching may be performed by a dry etching process, and examples of the dry etching may be plasma etching, ion beam milling, RIE, MERIE, ICP, TCP, and ECR.

Since the second nitride layer pattern 140 is disposed on the sidewalls of the first gap 130a, a size of the second gap 140a may be smaller than the size of the first gap 130a. In particular, a minimum gap G2 of the second gap 140a is smaller than a minimum gap G1 of the first gap 130a. Since the minimum gap G1 of the first gap 130a has a micron size, the minimum gap G2 of the second gap 140a may have a nano size. For example, the minimum gap G2 of the second gap 140a may be in a range of about 100 nm to about 1000 nm.

Meanwhile, the thickness of the second nitride layer 135 is adjusted when the second nitride layer 135 is formed, and thus, the size of the second gap 140a or a size of the minimum gap G2 of the second gap 140a may be adjusted. Specifically, in the case that the thickness of the second nitride layer 135 is relatively thin, a difference between the minimum gap G1 of the first gap 130a and the minimum gap G2 of the second gap 140a is small. Therefore, the size of the minimum gap G2 of the second gap 140a is relatively large. In the case that the thickness of the second nitride layer 135 is relatively thick, the difference between the minimum gap G1 of the first gap 130a and the minimum gap G2 of the second gap 140a is large. Therefore, the size of the minimum gap G2 of the second gap 140a is relatively small.

Also, the size of the second gap 140a or the size of the minimum gap G2 of the second gap 140a may be adjusted according to time of the anisotropic etching process. Specifically, in the case that the time of the anisotropic etching process is long, a relatively large amount of the second nitride 135 layer is etched such that the thickness of the second nitride layer pattern 140 is low, and thus, the size of the second gap 140a or the minimum gap G2 of the second gap 140a may be large. Alternatively, in the case that the time of the anisotropic etching process is short, a relatively small amount of the second nitride layer 135 is etched such that the thickness of the second nitride layer pattern 140 is high. Therefore, the size of the second gap 140a or the minimum gap G2 of the second gap 140a may be small.

Referring to FIGS. 1 and 9, the oxide layer 115 is etched by using the second nitride layer pattern 140 as an etching mask to form an oxide layer pattern 145 having a third gap 145a (S160).

At this time, the formation of the oxide layer pattern 145 may be performed by a wet etching process.

Meanwhile, as another example, the formation of the oxide layer pattern 145 at this time may be performed by a dry etching process and an etch back process.

A pattern 150 having a nano-sized gap may be formed on the substrate 110 through the foregoing process.

According to a method of forming the nanogap pattern, the first gap 130a of the first nitride layer pattern 130 is formed to have a micron size and the second nitride layer 135 formed along the first nitride layer pattern 130 is then dry etched to form the second nitride layer pattern 140 having the nano-sized second gap 140a smaller than the micron-sized first gap 130a on the side walls of the first gap 130a.

As described above, the size of the gap may be decreased from a micron size to a nano size by using a dry etching process, and the second gap 140a may be formed to have a desired size by controlling the size of the first gap 130a, the thickness of the second nitride layer 135, and the time of the dry etching process. Therefore, the gap size of the pattern 150 may be easily adjusted according to a type of a material to be detected in a biosensor.

Also, the substrate 110 having the oxide layer 115 and the first nitride layer pattern 130 having the first gap 130a formed thereon may be used regardless of the type of the detection target material. Therefore, the substrate 110 having the oxide layer 115 and the first nitride layer pattern 130 having first gap 130a formed thereon, that is, the substrate in a state illustrated in FIG. 6, is mass produced in advance and the pattern 150 having various nano-sized gaps may be formed by controlling a subsequent process according to the type of the detection target material. Therefore, productivity of the method of forming a nanogap pattern may be improved.

Since the second nitride layer pattern 140 having the nano-sized second gap 140a is formed by using the dry etching process, the second gap 140a may be formed to have a uniform size and the second gap 140a may be reproducibly formed to have a desired size.

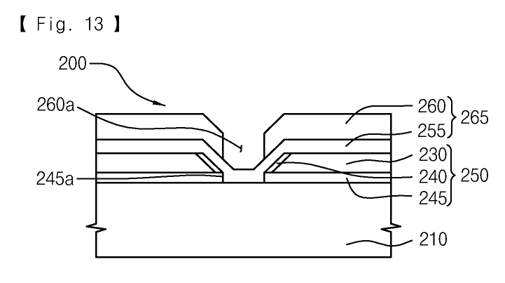

FIG. 10 is a cross-sectional view illustrating a biosensor according to an embodiment of the present invention.

Referring to FIG. 10, a biosensor 200 includes a substrate 210, a nanogap pattern 250 and a gate electrode 265.

The substrate 210 may be a single crystal silicon substrate. Since a low cost single crystal substrate may be used as the substrate 210 instead of using a relatively expensive SOI substrate, costs required during formation of a pattern having the nanogap may be reduced.

The nanogap pattern 250 is disposed on the substrate 250, and includes an oxide layer pattern 245, a first nitride layer pattern 230, and a second nitride layer pattern 240.

The oxide layer pattern 245 is disposed on the substrate 210 and may have a third nanogap 245a. For example, sidewalls of the third gap 245a may have an inclined profile to allow the third gap 245a to be gradually widened from a top portion to a bottom portion thereof. As another example, the sidewalls of the third gap 245a may have a vertical profile. At this time, the third gap 245a has a nano size.

The first nitride layer pattern 230 is disposed on the oxide layer pattern 245 and has a first gap 230a. Sidewalls of the first gap 230a may have an inclined profile. For example, the first gap 230a may be formed to gradually narrow in a downward direction. An inclination angle of the sidewalls of the first gap 230a may be in a range of about 15 degrees to about 75 degrees. For example, the inclination angle of the sidewalls of the first gap 230a may be in a range of about 30 degrees to about 60 degrees.

A minimum size of the first gap 230a is greater than a size of the third gap 245a. Therefore, the oxide layer pattern 245 around the third gap 245a is partially exposed by the first gap 230a. Also, the third gap 245a has a nano size, but the first gap 230a may have a micron size.

The second nitride layer pattern 240 is disposed on the sidewalls of the first gap 230a and the oxide layer pattern 245 exposed by the first gap 230a, and has a second gap 240a.

Since the second nitride layer pattern 240 is disposed on the sidewalls of the first gap 230a and the oxide layer pattern 245, a minimum gap G2 of the second gap 240a is smaller than a minimum gap G1 of the first gap 230a. Since the minimum gap G1 of the first gap 230a has a micron size, the minimum gap G2 of the second gap 240a may have a nano size. For example, the minimum gap G2 of the second nitride layer pattern 240 may be in a range of about 100 nm to about 1000 nm.

In the nanogap pattern 250, the first gap 230a has a micron size, and the second gap 240a and the third gap 245a may each have a nano size.

The gate electrode 265 is disposed on the nanogap pattern 250 and may include a gate dielectric layer 255 and a gate conductive layer pattern 260.

The gate dielectric layer 255 is disposed along the nanogap pattern 250 and a surface of the substrate 210 exposed by the third gap 245a. The gate dielectric layer 255 may be formed by a chemical vapor deposition process and examples of the gate dielectric layer 255 may be an oxide layer, a nitride layer, and an oxynitride layer.

The gate conductive layer pattern 260 is disposed on the gate dielectric layer 255 and has a fourth gap 260a. The fourth gap 260a exposes the gate dielectric layer 255 formed at a position of the third gap 245a.

The gate conductive layer pattern 260 may include a metallic material. Gold (Au) is mainly used as the gate conductive layer pattern 260, but in some cases, materials, such as aluminum (Al) and tungsten (W), may be used in which an antibody for a specific purpose may be attached thereto. Also, the gate conductive layer pattern 260 may have a single layer structure or a composite layer structure. In the case that the gate conductive layer pattern 260 has a composite layer structure, an adhesive layer pattern may be disposed between the conductive layer patterns forming the composite layer structure. A thickness of the gate conductive layer pattern 260 may be less than about 1000 nm.

As a specific example of the gate electrode 265, about 20 nm thick aluminum oxide (Al₂O₃) is formed as the gate dielectric layer 255, and about 5 nm thick chromium (Cr) and about 20 nm thick Au may be formed as the gate conductive layer pattern 260. At this time, an adhesive layer may be formed between chromium and gold.

It is described above that the gate electrode 265 includes the gate dielectric layer 255 and the gate conductive layer pattern 260. However, since the first nitride layer pattern 230 and the second nitride layer pattern 240 may perform the same function as that of the gate dielectric layer 255, the gate dielectric layer 255 may be omitted, and the gate electrode 265 may only include the gate conductive layer pattern 260.

In the biosensor 200, the nano-sized nanogap pattern 250 may be easily formed by disposing the second nitride layer pattern 240 on the sidewalls of the first gap 230a and the oxide layer pattern 245 exposed by the first gap 230a.

Also, the biosensor 200 may effectively detect a biomaterial by forming the gate electrode 265 exposing the nano-sized gap on the nanogap pattern 250.

FIG. 11 is a flowchart illustrating a method of manufacturing a biosensor according to an embodiment of the present invention, and FIGS. 12 and 13 are cross-sectional views illustrating the method of manufacturing a biosensor illustrated in FIG. 11.

Referring to FIGS. 11 and 12, the pattern 250 having a nanogap is formed on the substrate 210 (S210).

The pattern 250 includes the oxide layer pattern 245, the first nitride layer pattern 230, and the second nitride layer pattern 240. The oxide layer pattern 245 is disposed on the substrate 210 and has the third gap 245a. The first nitride layer pattern 230 is disposed on the oxide layer pattern 245 and has the first gap 230a. The second nitride layer pattern 240 is disposed on the side walls of the first gap 230a and has a second gap 240a.

Since a method of forming the pattern 250 is substantially the same as the method of forming a pattern with reference to FIG. 1 and FIGS. 2 to 9, detailed descriptions thereof will be omitted.

Referring to FIGS. 11 and 13, the biosensor 200 is completed by forming the gate electrode 265 including the gate dielectric layer 255 and the gate conductive layer patter 260 on the nanogap pattern 250.

Specifically, the gate dielectric layer 255 is formed along the nanogap pattern 250 and the surface of the substrate 210 exposed by the third gap 245a.

The gate dielectric layer 255 may be formed by a chemical vapor deposition process and examples of the gate dielectric layer 255 may be an oxide layer, a nitride layer, and an oxynitride layer.

Next, a mask (not shown) covering the gate dielectric layer 255 formed at the position of the third gap 245a and exposing other portions of the gate dielectric layer 255 is disposed on the gate dielectric layer 255. A gate conductive layer is formed on the gate dielectric layer 255 in a state of having the mask disposed thereon and the gate conductive layer pattern 260 having the fourth gap 260a is then formed by removing the mask.

The gate conductive layer may be formed by a chemical vapor deposition process and the gate conductive layer may include a metallic material. Au is mainly used as the gate conductive layer, but in some cases, materials, such as Al and W, may be used in which an antibody for a specific purpose may be attached thereto. Also, the gate conductive layer may have a single layer structure or a composite layer structure. In the case that the gate conductive layer has a composite layer structure, an adhesive layer pattern may be disposed between the conductive layers forming the composite layer structure. A thickness of the gate conductive layer may be less than about 1000 nm.

As a specific example of the gate electrode 265, about 20 nm thick Al₂O₃ is formed as the gate dielectric layer 255, and about 5 nm thick Cr and about 20 nm thick Au may be formed as the gate conductive layer pattern 260. At this time, an adhesive layer may be formed between chromium and gold.

It is described above that a process of forming the gate electrode 265 is performed by forming the gate conductive layer pattern 260 after forming the gate dielectric layer 255. However, since the second insulation layer pattern 230 and the third insulation layer pattern 240 may perform the same function as that of the gate dielectric layer 255, a process of forming the gate dielectric layer 255 may be omitted, and a process of forming the gate electrode 265 may only be performed by a process of forming the gate conductive layer pattern 260.

Since the size of the gap may be decreased from a micron size to a nano size by using a dry etching process, the method of manufacturing a biosensor may form a nanogap pattern 250 having a uniform size. Also, the second gap 240a may be reproducibly formed to have a desired size by controlling the size of the first gap 230a, the thickness of the second nitride layer 235, and the time of the dry etching process.

Further, according to the method of manufacturing a biosensor, the gate electrode 265 having the same nano-sized gap as the gap of the nanogap pattern 250 may be formed and as a result, the biosensor 200 having a nano-sized gap may be manufactured.

### INDUSTRIAL APPLICABILITY

As described above, since the size of the gap may be decreased from a micron size to a nano size by using a dry etching process, a method of forming a nanogap pattern may form a nanogap pattern having a uniform size.

Also, the second gap may be reproducibly formed to have a desired size by controlling the size of the first gap of the first nitride layer, the thickness of the second nitride layer, and the time of the dry etching process.

Since a single crystal silicon substrate may be used, costs for manufacturing a biosensor may be reduced in comparison to the related art.

A substrate having the nitride layer pattern having the first gap formed thereon may be used regardless of a type of a detection target material. Therefore, the substrate having the nitride layer pattern having the first gap formed thereon is mass produced in advance and a pattern or a biosensor having various nano-sized gaps may be formed by controlling a subsequent process according to the type of the detection target material. Therefore, productivities of the method of forming a nanogap pattern and the method of manufacturing a biosensor may be improved.

While this invention has been particularly shown and described with reference to preferred embodiments thereof, it will be understood by those skilled in the art that various changes in form and details may be made therein without departing from the spirit and scope of the invention as defined by the appended claims.

1. A method of forming a nanogap pattern, the method comprising:
forming an oxide layer on a substrate;
forming a first nitride layer on the oxide layer;
partially etching the first nitride layer to form a first nitride layer pattern having a first gap that exposes the oxide layer and gradually narrows from a top portion to a bottom portion thereof;
forming a second nitride layer along the first nitride layer and along sidewalls and a bottom surface of the first gap; and
etching the second nitride layer to form a second nitride layer pattern having a second gap narrower than the first gap on the sidewalls of the first gap.

2. The method of claim 1, further comprising etching the oxide layer by using the second nitride layer pattern as an etching mask to form an oxide layer pattern having a third gap.

3. The method of claim 2, wherein the first gap has a micron size, and the second gap and the third gap each have a nano size.

4. The method of claim 1, wherein an inclination angle of the first gap is in a range of 15 degrees to 75 degrees.

5. A biosensor comprising:
a substrate;
a nanogap pattern including an oxide layer pattern disposed on the substrate and having a third gap, a first nitride layer pattern disposed on the oxide layer pattern and having a first gap that partially exposes the oxide layer pattern around the third gap and gradually narrows from a top portion to a bottom portion thereof, and a second nitride layer pattern disposed on sidewalls of the first gap and the oxide layer pattern exposed by the first gap and having a second gap narrower than the first gap; and
a gate electrode disposed on the nanogap pattern and including a gate conductive layer pattern.

6. The biosensor of claim 5, wherein the first gap has a micron size, and the second gap and the third gap each have a nano size.

7. The biosensor of claim 5, wherein an inclination angle of the first gap is in a range of 15 degrees to 75 degrees.

8. A method of manufacturing a biosensor, the method comprising:
forming a nanogap pattern having a nanogap on a substrate; and
forming a gate electrode including a gate conductive layer pattern on the nanogap pattern,
wherein the forming of the nanogap pattern having the nanogap comprises:
forming an oxide layer on the substrate;
forming a first nitride layer on the oxide layer;
partially etching the first nitride layer to form a first nitride layer pattern having a first gap that exposes the oxide layer and gradually narrows from a top portion to a bottom portion thereof;
forming a second nitride layer along the first nitride layer and along sidewalls and a bottom surface of the first gap;
etching the second nitride layer to form a second nitride layer pattern having a second gap narrower than the first gap on the sidewalls of the first gap; and
etching the oxide layer by using the second nitride layer pattern as an etching mask to form an oxide layer pattern having a third gap.

9. The method of claim 8, the first gap has a micron size, and the second gap and the third gap each have a nano size.

10. The method of claim 8, wherein an inclination angle of the first gap is in a range of 15 degrees to 75 degrees.
